(19) United States
(12) Patent Application Publication
(10) Pub. No.: US 2004/0157464 A1
(43) Pub. Date: Aug. 12, 2004

(54) Manufacturing method of electronic device having wiring connection structure

(75) Inventor: Junko Izumitani, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/608,028

(22) Filed: Jun. 30, 2003

(30) Foreign Application Priority Data
Feb. 7, 2003 (JP) 2003-030381

(51) Int. Cl. H01L 21/302; H01L 21/461

(52) U.S. Cl. 438/723

(57) ABSTRACT

A manufacturing method of an electronic device having a wiring connection structure which can prevent a loose connection between a via plug and a metal wiring is obtained. In an etching process to form a via hole (8), a mixed gas of C₄H₈, O₂ and Ar is employed as an etching gas. According to this, a surface of a side wall of the via hole (8) has a smooth shape without a microscopic unevenness on an upper part of the side wall of the via hole (8) at least. Accordingly, a gap caused by the microscopic unevenness described above does not occur between a barrier metal film (9) and the side wall of the via hole (8), and both sides stick to each other. As a result, in a cleaning process employing a hydrofluoric acid after a CMP process, a cleaning solution does not penetrate a metal film (3) through the gap between the barrier metal film (9) and the side wall of the via hole (8).

### BACKGROUND OF THE INVENTION

1. Field of the Invention

The present invention relates to a manufacturing method of an electronic device having a wiring connection structure, and more concretely, it relates to a forming method of a via plug to connect a lower layer and an upper layer with each other in a multilayer wiring structure that the electronic device has.

2. Description of the Background Art

In a conventional forming method of a via plug, a step (a) of forming an interlayer insulating film with covering a metal wiring, a step (b) of forming a photoresist having a pattern that exposes a portion of an upper surface of the interlayer insulating film above the wiring on the upper surface of the interlayer insulating film, a step (c) of removing the interlayer insulating film by performing an anisotropic etching with, employing the photoresist as an etching mask to form a via hole and according to this, exposing the metal wiring, step (d) of removing the photoresist, a step (e) of forming a metal film on a structure obtained by the step (d), a step (f) of removing the metal film of a part that exists above the upper surface of the interlayer insulating film by a CMP (Chemical Mechanical Polishing) method and a step (g) of cleaning a surface of a structure obtained by the step (f) with employing a cleaning solution which has the property of dissolving a material of the metal wiring are performed in this order. Especially, in the step (c), an anisotropic dry etching by a plasma employing a mixed gas, of C₅F₈, O₂ and Ar or by a plasma employing a mixed gas of C₄F₈, O₂ and Ar is performed.

Besides, a technique relating to the manufacturing method of the electronic device having the wiring connection structure is disclosed in Japanese Patent Application Laid-Open Nos. 11-186390 (1999), 9-162281 (1997), 10-32251 (1998) and 8-250497 (1996).

However, according to the conventional forming method of the via plug, an etching of the photoresist proceeds inhomogeneously in the anisotropic etching of the step (c). Especially, that tendency is noticeable in a shoulder part of the photoresist near a opening surface of the via hole, and parts that a film of the photoresist decreases rapidly and slowly appear at random. Accordingly, numerous microscopic unevenness arise on a surface of an upper part of a side wall of the via hole.

In the step (e), the metal film is formed in the via hole, a gap occurs between the side wall of the via hole and the metal film caused by the microscopic unevenness described above. Then, in the step (g), the cleaning solution penetrates the metal wiring through the gap described above, dissolves the metal wiring and causes a void. As a result, there is a problem that a loose connection occurs between the via plug and the metal wiring.

### SUMMARY OF THE INVENTION

It is an object of the present invention to obtain a manufacturing method of a electronic device which has a wiring connection structure that a loose connection between a via plug and a metal wiring can be prevented.

According to the present invention, the manufacturing method of the electronic device having the wiring connection structure includes steps (a) to (h) in the following. In the step (a), a wiring is formed on a substrate. In the step (b), an interlayer insulating film is formed with covering the wiring. In the step (c), a mask material having a pattern that exposes a portion of said upper surface of said interlayer insulating film above said wiring is formed on an upper surface of the interlayer insulating film. In the step (d), by performing an anistropic etching with employing the mask material as an etching mask, the interlayer insulating film is removed to form a concave part, and according to this, the wiring is exposed. In the step (e), the mask material is removed. In the step (f), a conductive film is formed on a structure obtained by the step (e) with filling up the concave part. In the step (g), the conductive film of a part that is formed on the upper surface of the interlayer insulating film is removed. In the step (h), a surface of a structure obtained by the step (g) is cleaned with employing a cleaning solution which has the property of dissolving a material of the wiring. By performing the anistropic etching with employing a predetermined etching gas in the step (d), a side wall of the concave part has a smooth shape without the microscopic unevenness in a vicinity of the upper surface of the interlayer insulating film at least.

The conductive film can be formed with making it stick to the side wall of the concave part. Accordingly, in the step (h), the cleaning solution does not dissolve the wiring by penetrating the wiring, thus a loose connection between the conductive film and the wiring can be prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 9 are drawings all illustrating a manufacturing method of an electronic device having a wiring connection structure in order of steps according to a first preferred embodiment of the present invention.

FIGS. 10 and 11 are cross sectional views both illustrating a manufacturing method of an electronic device having a wiring connection structure in order of steps according to a third preferred embodiment of the present invention.

FIGS. 12 and 13 are cross sectional views both illustrating a manufacturing method of an electronic device having a wiring connection structure in order to steps according to a fourth preferred embodiment of the present invention.

### DESCRIPTION OF THE PREFERRED EMBODIMENTS

First preferred embodiment

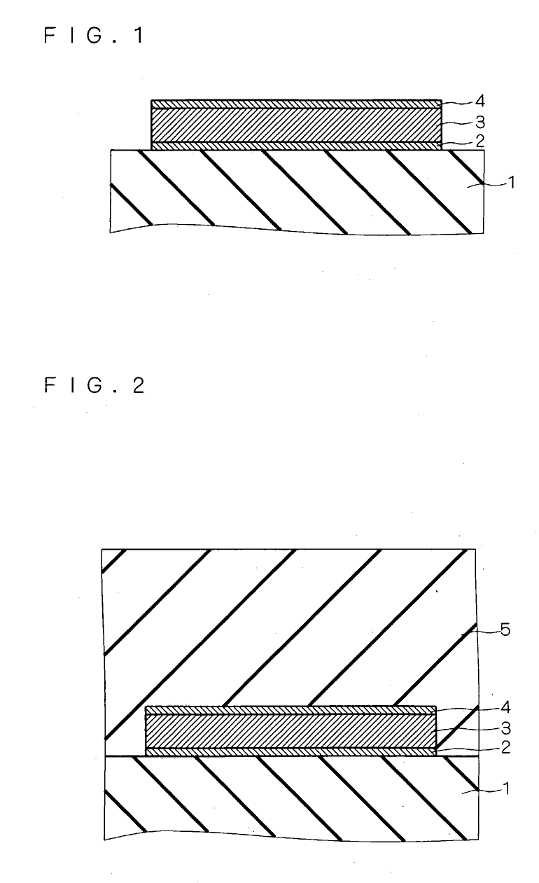

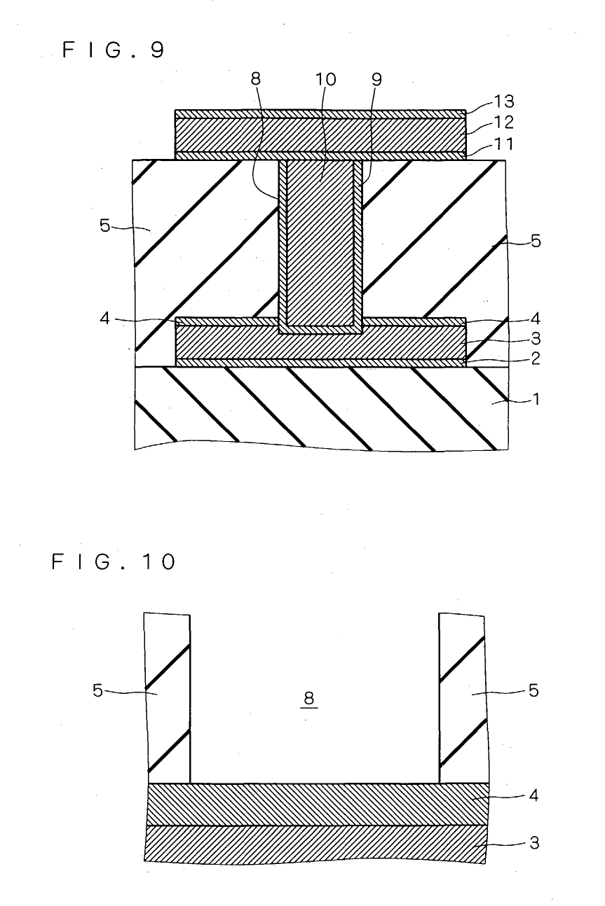

FIGS. 1 to 9 are drawings all illustrating a manufacturing method of an electronic device having a wiring connection structure in order of steps according to a first preferred embodiment of the present invention. Especially, FIGS. 1 to 7 and 9 are cross section views, and FIG. 8 is a top surface view corresponding to a position along a line VIII-VIII shown in FIG. 7.

First, referring to FIG. 1, an underlay film composed of a titanium (Ti) film, a nitride titanium (TiN) film, or a laminated film of these films is formed entirely on an upper surface of an interlayer insulating film 1 by a PVD method. Next, a metal film composed of an aluminum alloy such as Al—Cu, Al—Si—Cu, Al—Cu—Ti or the like is formed entirely on an upper surface of the underlay film by the PVD method. Next, a top layer film composed of a nitride titanium is formed entirely on an upper surface of the metal film. The top layer film functions as an antireflection film. Next, by patterning these films by a photolithography method and an anistropic dry etching method, a first metal wiring composed of an underlay film 2, a metal film 3 and a top layer film 4 is formed.

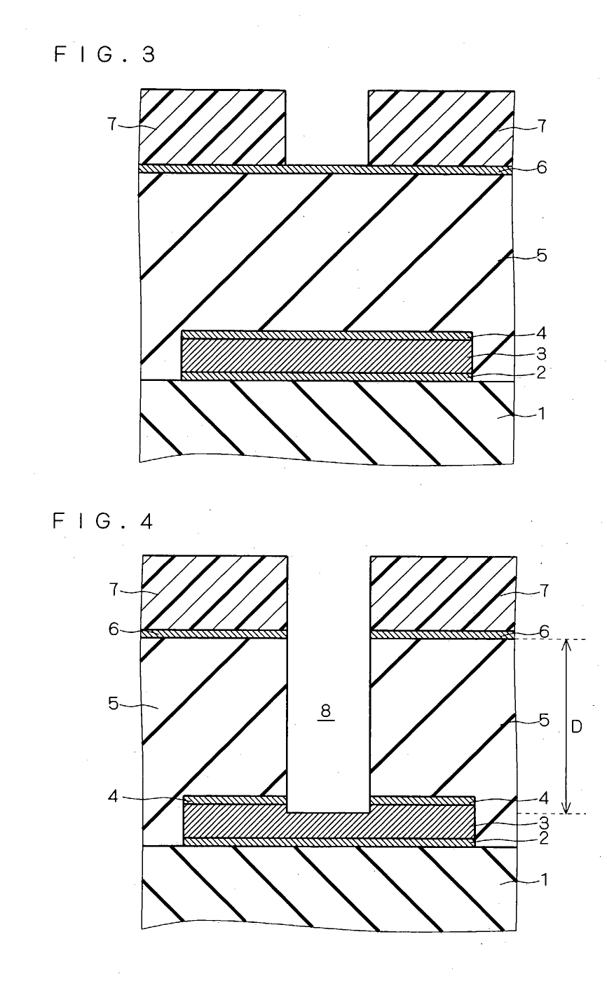

Next, referring to FIG. 2, a silicon oxide film is formed entirely on the upper surface of the interlayer insulating film 1 with covering the first metal wiring by a CVD method employing a plasma of high density and so on. Next, an interlayer insulating film 5 is formed by flattening an upper surface of the silicon oxide film by the CMP method. The interlayer insulating film 5 can also be formed by applying a SOG (Spin On Glass) film on the silicon oxide film after forming the silicon oxide film by the CVD method. By either method, the interlayer insulating film 5 whose upper surface is flattened can be obtained.

Next, referring to FIG. 3, an underlay film 6 composed of a polymer resin is applied entirely on an upper surface of the interlayer insulating film 5. The underlay film 6 functions as an antireflection film. Next, a photoresist 7 composed of KrF or ArF is formed on an upper surface of the underlay film 6 by the photolithography method. The photoresist 7 has an opening pattern that exposes a portion of the upper surface of the interlayer insulating film 5 above the first metal wiring.

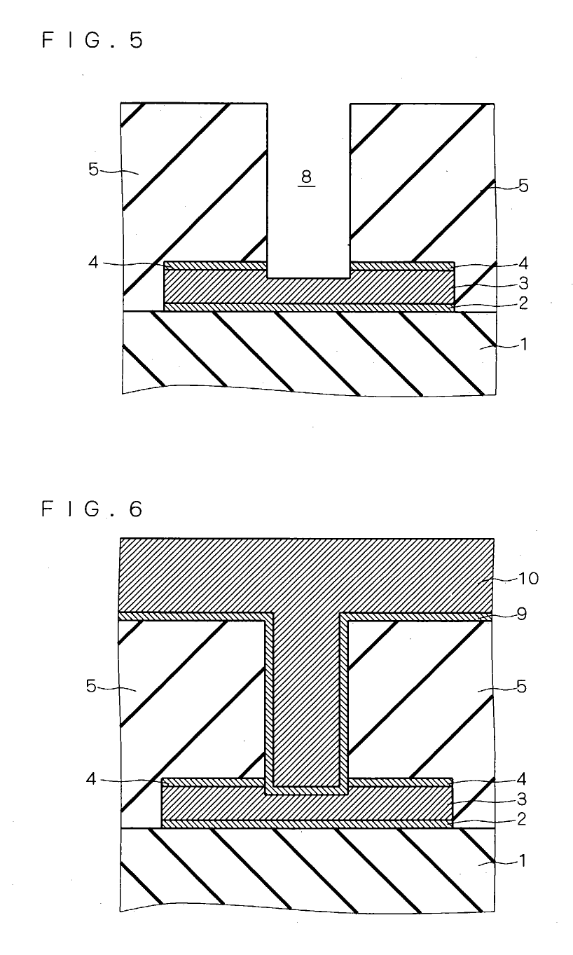

Next, referring to FIG. 4, the underlay film 6, the interlayer insulating film 5, the top layer film 4 and upper part of the metal film 3 are removed in this order by the anistropic dry etching method with employing the photoresist 7 as an etching mask. According to this, a via hole 8 is formed. By forming the via hole 8 so as to reach the metal film 3, a contact resistance between the first metal wiring and a via plug formed afterwards can be reduced. Here, as for an etching gas, a gas that C₄H₈, O₂ and Ar are mixed at a mixing ratio of C₄H_{8:02}: Ar=18:14:600, for example, is employed. By employing that etching gas, a surface of a side wall of the via hole 8 comes to have a smooth shape without the microscopic unevenness. It is important that the surface should be smooth on an upper part of the side wall (a vicinity of an opening surface) of the via hole 8 at least.

Next, referring to FIG. 5, the photoresist 7 is removed by an ashing. Next, scum of a deposition film generated in an etching process to form the via hole 8, a polymer formed by the ashing and so on are removed by a cleaning with employing an abruption solution such as a EKC 265 solution and so on.

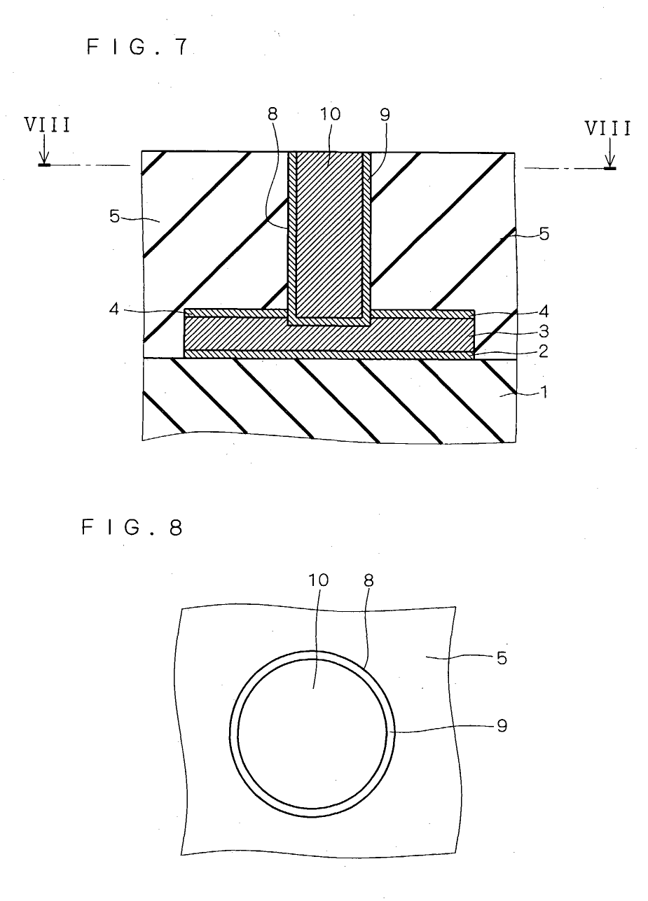

Next, referring to FIG. 6, a barrier metal film 9 composed of a laminated film of a titanium film and a nitride titanium film is formed entirely on a structure shown in FIG. 5 by the CVD method. The barrier metal film 9 is formed on a side wall and a bottom surface of the via hole 8, and on the upper surface of the interlayer insulating film 5. As described above, the surface of the side wall of the via hole 8 has a smooth shape without the microscopic unevenness. Accordingly, a gap caused by the microscopic unevenness described above does not occur between the barrier metal film 9 and the side wall of the via hole 8, and both sides stick to each other.

Next, a metal film 10 composed of tungsten is formed entirely on the barrier metal film 9 by the CVD method. The via hole 8 is completely filled up with the barrier metal film 9 and the metal film 10. The metal film 10 is also formed above the via hole 8 and an above the interlayer insulating film 5 of a part that the via hole 8 is not formed.

Next, referring to FIG. 7, the metal film 10 and the barrier metal film 9 are polished so that the upper surface of the interlayer insulating film 5 is exposed by the CMP method employing an alumina abrasive or a silica abrasive on the basis of a hydrogen peroxide solution (H₂O₂). According to this, the metal film 10 and the barrier metal film 9 in a part which exists above the upper surface of the interlayer insulating film 5 are removed. As a result, a via plug is formed as the metal film 10 and the barrier metal film 9 which remain in the via hole 8 without being removed.

Next, in order to remove an abrasive and so on which remain on a surface of a structure shown in FIG. 7, the surface of the structure shown in FIG. 7 is cleaned with employing a cleaning solution composed of a hydrofluoric acid (HF). The hydrofluoric acid has the property of dissolving the aluminum alloy which is a material of the metal film 3. Referring to FIG. 8, the surface of the side wall of the via hole 8 has the smooth shape without the microscopic unevenness. Moreover, the barrier metal film 9 and the side wall of the via hole 8 stick to each other without a gap. Accordingly, the cleaning solution does not penetrate the metal film 3 through the gap between the barrier metal film 9 and the side wall of the via hole 8.

Next, referring to FIG. 9, a second metal wiring composed of an underlay film 11, a metal film 12 and a top layer film 13 is formed on the upper surface of the interlayer insulating film 5 by a similar method to the steps illustrated in FIG. 1. The second metal wiring is connected with the first metal wiring through the via plug.

In this manner, according to the manufacturing method of the electronic device having the wiring connection structure according to the first preferred embodiment, in the etching process to form the via hole 8 (in FIG. 4), the mixed gas of C₄H₈, O₂ and Ar is employed as the etching gas. According to this, the surface of the side wall of the via hole 8 has the smooth shape without the microscopic unevenness on the upper part of the side wall of the via hole 8 at least. Accordingly, the gap caused by the microscopic unevenness described above does not occur between the barrier metal film 9 and the side wall of the via hole 8, and both sides stick to each other. As a result, in a cleaning process employing the hydrofluoric acid after the CMP process shown in FIG. 7, the cleaning solution does not penetrate the metal film 3 through the gap between the barrier metal film 9 and the side wall of the via hole 8. Accordingly, the cleaning solution does not dissolve the metal film 3 and the void is not made to occur, thus a loose connection between the via plug and the first metal wiring can be prevented.

Second Preferred Embodiment

Titanium included in the barrier metal film 9 has solubility to the hydrofluoric acid. Accordingly, if the barrier metal film 9 is completely dissolved in the cleaning process employing the hydrofluoric acid, the cleaning solution penetrates the metal film 3 through a gap occurred after the barrier metal film 9 is dissolved, even if the gap does not occur between the barrier metal film 9 and the side wall of the via hole 8.

In order to prevent this, in a second preferred embodiment, a depth D of the via hole 8 (refer to FIG. 4) is set to be a depth to a degree that the barrier metal film 9 formed on the side wall of the via hole 8 is not completely dissolved by the cleaning.

Concretely, the cleaning after the CMP process shown in FIG. 7 is the cleaning of approximately 5 to 30 seconds employing a dilute hydrofluoric acid. Although depending on a deposition method of the barrier metal film 9, within this time, a dissolution of the barrier metal film 9 by the dilute hydrofluoric acid proceeds to a depth of approximately 100 to 200 nm from an upper surface of the via plug to a bottom surface of it. Accordingly, in the second preferred embodiment, a film thickness of the interlayer insulating film 5 are set to ensure the depth D of the via hole 8 to be 300 nm or more on the safe side.

In this manner, according to the manufacturing method of the electronic device having the wiring connection structure according to the second preferred embodiment, in the cleaning process after the CMP process shown in FIG. 7, the barrier metal film 9 is not completely dissolved by the cleaning solution. Accordingly, it is possible to prevent the cleaning solution from penetrating the metal film 3 through the gap occurred after the barrier metal film 9 is dissolved.

Third Preferred Embodiment

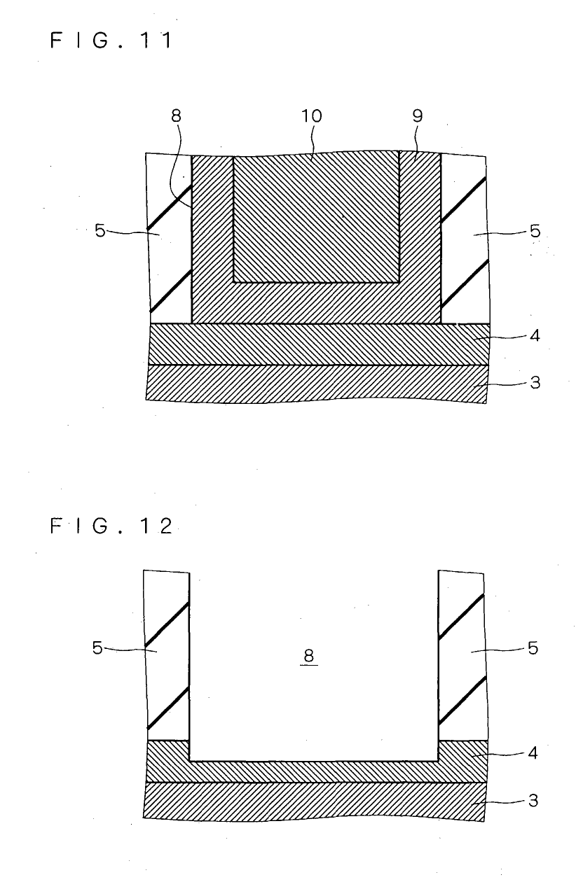

FIGS. 10 and 11 are cross sectional views both illustrating a manufacturing method of an electronic device having a wiring connection structure in order of steps according to a third preferred embodiment of the present invention. Especially, they are drawings both illustrating an enlarged vicinity of the bottom surface of the via hole 8 corresponding to an etching process to form the via hole 8.

In the first preferred embodiment described above, as shown in FIG. 4, the via hole 8 is formed so as to reach the metal film 3 with going through the top layer film 4. On the contrary, in the third preferred embodiment, as shown in FIG. 10, the anisotropic dry etching to form the via hole 8 is stopped when an upper surface of the top layer film 4 is exposed. As a result, the bottom surface of the via hole 8 is defined by the upper surface of the top layer film 4, and the metal film 3 is not exposed.

Next, referring to FIG. 11, a via plug is formed through the similar steps to the first preferred embodiment described above. A bottom surface of the barrier metal film 9 is in contact with the upper surface of the top layer film 4, and the via plug and the metal film 3 are not in contact with each other.

In this manner, according to the manufacturing method of the electronic device having the wiring connection structure according to the third preferred embodiment, the bottom surface of the via plug is in contact with the upper surface of the top layer film 4 instead of the metal film 3. Nitride titanium which is the material of the top layer film 4 does not have solubility to the hydrofluoric acid. Accordingly, even in case that the gap occurs between the barrier metal film 9 and the side wall of the via hole 8 or the barrier metal 9 is completely dissolved by the cleaning solution, penetration of the cleaning solution from the upper surface of the via plug stops on the top layer 4. As a result, the dissolution of the metal film 3 by the cleaning solution can be prevented.

Fourth Preferred Embodiment

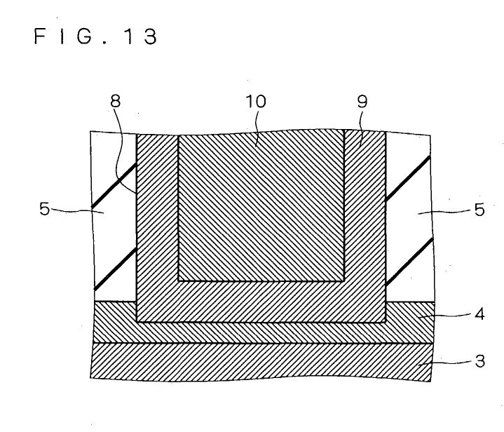

FIGS. 12 and 13 are cross sectional views both illustrating a manufacturing method of an electronic device having a wiring connection structure in order to steps according to a fourth preferred embodiment of the present invention corresponding to FIGS. 10 and 11.

In the fourth preferred embodiment, as shown in FIG. 12, an anisotropic dry etching to form the via hole 8 is stopped in process of etching the top layer film 4. By forming the top layer film 4 in a film thickness of appropriately 60 to 150 nm and controlling an etching time, the etching is stopped before the etching proceeds to the bottom surface of the top layer film 4 after the upper surface of the top layer film 4 is exposed. As a result, the bottom surface of the via hole 8 is defined by the top layer film 4, and the metal film 3 is not exposed.

Next, referring to FIG. 13, a via plug is formed through the similar steps to the first preferred embodiment described above. In the same manner as the third preferred embodiment described above, the via plug and the metal film 3 are not in contact with each other.

Also according to the manufacturing method of the electronic device having the wiring connection structure according to the fourth preferred embodiment, in the same manner as the third preferred embodiment described above, the dissolution of the metal film 3 by the cleaning solution can be prevented.

Besides, as for an example of electronic devices to which the present invention is applicable, semiconductor devices such as a LSI and so on, and liquid crystal devices and so on are mentioned.

While the invention has been shown and described in detail, the foregoing description is in all aspects illustrative and not restrictive. It is therefore understood that numerous modifications and variations can be devised without departing from the scope of the invention.

What is claimed is:

1. A manufacturing method of an electric device having a wiring connection structure, comprising steps of:
(a) forming a wiring on a substrate;
(b) forming an interlayer insulating film with covering said wiring;
(c) forming on an upper surface of said interlayer insulating film a mask material having a pattern that exposes a portion of said upper surface of said interlayer insulating film above said wiring;
(d) performing an anistropic etching with employing said mask material as an etching mask, so that said interlayer insulating film is removed to form a concave part, and according to this, said wiring is exposed;
(e) removing said mask material;
(f) forming a conductive film on a structure obtained by said step (e) with filling up said concave part;
(g) removing said conductive film of a part which is formed on said upper surface of said interlayer insulating film; and
(h) cleaning a surface of a structure obtained by said step (g) with employing a cleaning solution which has the property of dissolving a material of said wiring, wherein
in said step (d), by performing said anistropic etching with employing a predetermined etching gas, a side wall of said concave part has a smooth shape without a microscopic unevenness in a vicinity of said upper surface of said interlayer insulating film at least.

2. The manufacturing method of the electronic device having the wiring connection structure according to claim 1, wherein
said predetermined etching gas is a mixed gas of C₄H₈, O₂ and Ar.

3. The manufacturing method of the electronic device having the wiring connection structure according to claim 1, wherein
said step (f) includes steps of:
(f-1) forming a barrier metal film composed of a material which has solubility to said cleaning solution; and
(f-2) forming a metal film on said barrier metal film, wherein
in said step (d), a depth of said concave part is set to be a depth that said barrier metal film formed on a side surface of said concave part by said step (f) is not completely dissolved by a cleaning in said step (h).

4. The manufacturing method of the electronic device having the wiring connection structure according to claim 1, wherein
said wiring includes:
a metal film composed of a material which has solubility to said cleaning solution; and
a top layer film which is formed on said metal film and composed of a material which does not have solubility to said cleaning solution, wherein
in said step (d), said anisotropic etching is stopped when said top layer film is exposed.

5. The manufacturing method of the electronic device having the wiring connection structure according to claim 1, wherein
said wiring includes:
a metal film composed of a material which has solubility to said cleaning solution; and
a top layer film which is formed on said metal film and composed of a material which does not have solubility to said cleaning solution, wherein
in said step (d), said anisotropic etching is stopped in process of etching said top layer film.
